(19) United States
(12) Patent Application Publication
(10) Pub. No.: US 2025/0389484 A1
(43) Pub. Date: Dec. 25, 2025

(54) DEVICE AND METHOD FOR TREATING A SUBSTRATE

(71) Applicant: AIXTRON SE, Herzogenrath (DE)

(72) Inventors: Karl-David LÄPPLE, Linköping (SE); Olof Claes Erik KORDINA, Vikingstad (SE); Martin ERIKSSON, Klockrike (SE)

(21) Appl. No.: 18/879,719

(22) PCT Filed: Jun. 26, 2023
(86) PCT No.: PCT/EP2023/067302

§ 371 Date: Dec. 27, 2024

(30) Foreign Application Priority Data
Jun. 29, 2022 (DE) 10 2022 002 350.4

(51) Int. Cl. F27B 17/00

(52) U.S. Cl. CPC F27B 17/0016

(57) ABSTRACT

A device for thermally treating a substrate with a heating apparatus arranged in a reactor housing to heat the substrate. During heating of the device, a flow of heat flows from the heating apparatus to a substrate, and during cooling, a flow of heat flows from the substrate to a cold region. To minimize the heating and cooling time, a shielding apparatus for influencing the flow of heat is provided that can be adjusted between a first and a second operating position. The shielding apparatus has several shielding elements that can be moved relative to one another.

### RELATED APPLICATIONS

This application is a National Stage under 35 USC 371 of and claims priority to International Application No. PCT/EP2023/067302, filed 26 Jun. 2023, which claims the priority benefit of DE Application No. 10 2022 002 350.4, filed 29 Jun. 2022.

### FIELD OF THE INVENTION

The invention relates to a device for thermally treating a substrate with a heating apparatus arranged in a reactor housing for heating the substrate, wherein a cold area is arranged in the reactor housing in such a way that a flow of heat flows from the heated substrate along a heat transfer path to the cold area, and with a shielding apparatus arranged in the heat transfer path, which is adjustable between a first and a second operating position, wherein the shielding apparatus exerts a greater shielding effect on the flow of heat in the first operating position than in the second operating position.

The invention further relates to a method for treating a substrate in such a device.

### BACKGROUND

Such a device is used in particular for depositing SiC. In a method according to the invention, substrates that are to be coated with a SiC layer are brought into the reactor housing, through a loading and unloading opening of a reactor housing, for example, where there is a process chamber which has a susceptor on which at least one substrate is placed. This can be done at a moderately elevated temperature, but also at temperatures up to 1000° C. The loading and unloading opening is closed. The process chamber is heated to a process temperature using a heating apparatus. At this process temperature, one or more layers are deposited on the substrate after any preparatory process steps. The process chamber and in particular the susceptor on which the substrate lies, or the substrate if it is kept free in the process chamber, is then cooled to the moderately elevated temperature so that it can then be removed from the process chamber through the loading and unloading opening. The process can subsequently be repeated with another substrate. In order to minimize the cycle time, which includes not only the process steps but also the heating and cooling steps, U.S. Pat. No. 8,430,965 B2 suggests a shielding apparatus which has a highly reflective surface and which is brought into a heat transport path during heating via which heat is transferred from the substrate to a cold area of the reactor housing. This reduces the flow of heat from the substrate. As the substrate cools, the shielding apparatus is removed from the heat transport path, so that the flow of heat from the substrate is increased.

Shielding devices that are used for other purposes in CVD reactors or the like are known in particular from DE 10 2010 000 447 A1 or DE 10 2017 103 055 A1, which discloses a shielding plate consisting of several sub-plates.

DE 10 2009 049 954 A1 describes a device for temperature control of substrates, with a shielding apparatus which has a multiplicity of adjustable shielding elements.

### SUMMARY OF THE INVENTION

The invention is based on the object of specifying a shielding apparatus that can be moved from a first to a second operating position using simple means and is arranged in a space-saving manner.

The object is solved by the invention specified in the claims. The subclaims represent not only advantageous developments of the invention specified in the independent claims, but also independent solutions to the problem.

The shielding apparatus according to the invention has a plurality of shielding elements that are movable relative to one another. It may be advantageous if these shielding elements remain within a heat transfer space through which the flow of heat flows during the displacement of the shielding apparatus between the first and second operating positions. The shielding elements may have various surface sections that may be brought selectively into the direction of the flow of heat. However, it is also possible for the shielding apparatus to consist of only a single shielding element, which is rotated when shifting between the two operating positions. It may have a large surface section that has a strong shielding effect on the flow of heat in the first operating position. It may have a small surface section which has a weak shielding effect on the flow of heat in the second operating position. For example, it may be provided that one or more shielding elements are flat, in particular rectangular strips that have a broad side surface and a narrow side surface. The shielding elements can be rotated about an axis of rotation in such a way that in the first operating position, they oppose their broad side surface to the flow of heat and in the second operating position they oppose their narrow side surface to the flow of heat. The axis of rotation of the one or more shielding elements may have a directional component that is perpendicular to the direction of flow of heat. However, the axis of rotation itself preferably runs perpendicularly to the direction of the flow of heat or at least substantially perpendicularly thereto. The shielding elements can pivot by, for example, 90 degrees between the two operating positions. But the shielding elements can also pivot around other, for example smaller or larger angles, wherein this angle may also be in a range between 45 and 90 degrees. According to a variant of the invention, it may be provided that at least two shielding elements can be moved relative to one another, so that they lie substantially next to one another in the first operating position and at least partially or completely overlap in the second operating position. The shielding elements may each be assigned to a shielding element carrier. The shielding element carrier may have a rectangular outline or a circular outline. A shielding element carrier that has a rectangular outline may have a plurality of narrow rectangular shielding elements arranged parallel to one another and extending in one plane, between which a free space extends which has approximately the same surface area as the shielding elements. By relative displacement of the shielding element carriers arranged in different but parallel planes, the shielding elements can be brought into an overlapping position in which a flow of heat can pass through the free spaces. In the overlapping position, the shielding elements lie on top of each other, overlapping each other. The shielding effect then depends on the degree of coverage. In the first operating position, the shielding elements are offset from one another in such a way that they close the free spaces of the respective other shielding element carrier. Alternatively, the shielding elements may also be circular sectors. The two shielding element carriers, which in such case are circular, can be rotated relative to one another about an axis of rotation, so that the free spaces are either closed or the shielding elements overlap. One of the two shielding element carriers may be connected fixedly to the reactor housing. The other shielding element carrier can be rotated about an axis of rotation. The axis of rotation preferably extends parallel to the direction of the flow of heat. One or more heating apparatus may be provided. A process chamber may be arranged between two heating apparatuses so that the process chamber is heated from below, for example, or from above. A process chamber may also be arranged inside a heating apparatus, as shown, for example, in the above-mentioned prior art, in which a coil extends around the process chamber, and generates a high-frequency alternating electromagnetic field. Bodies made of electrically conductive material may be present inside the process chamber. For example, the walls of the process chamber may be made of graphite. However, it is also possible for the process chamber to have a susceptor made of graphite. Eddy currents are generated in these electrically conductive bodies and heat up the bodies.

The eddy currents are generated inductively by alternating electromagnetic fields. The alternating electromagnetic fields are generated by a heating element. However, the heating element may also form a cold area if it is formed by a cooled coil, for example.

However, it is also possible to heat the walls of the process chamber or the susceptor by thermal radiation. It may further be provided that a coil, which can be a helical coil or which can be a spiral coil, has a cavity through which a coolant flows in order to cool the coil. The coil then not only has the function of supplying an energy flow with which a susceptor or a substrate is heated, but at the same time it also forms a heat sink. In such an arrangement, the shielding apparatus may be arranged between the coil and the susceptor or the substrate. If the coil is arranged above a process chamber ceiling, the shielding apparatus may be arranged between a ceiling plate and the heating apparatus, for example the coil. In such a constellation, it has been found to be advantageous if the shielding apparatus is transparent for alternating electromagnetic fields in the range of 10 kHz. The arrangement of the heating apparatus can be chosen such that the energy flow it generates to the substrate or to the susceptor flows through the same space through which the heat flows that the substrate or the susceptor transfers to the cold area, for example to an actively cooled zone of the reactor housing. The shielding elements preferably have at least one surface that has a high degree of reflection or a low degree of absorption. The degree of reflection for thermal radiation should preferably be greater than 0.6. But it may also be greater than 0.7 or 0.8. The degree of absorption for thermal radiation should preferably be less than 0.4. But it may also be less than 0.3 or less than 0.2. The surface in particular is highly reflective. The degree of reflection of the shielding element is in particular greater than the degree of reflection of the cold area. The shielding elements should be non-transparent to heat radiation. It is advantageous if the shielding elements can also be adjusted independently of one another. However, it is also provided that the shielding elements are coupled to one another, or that at least some of the shielding elements are coupled to one another, so that they can be moved by a common drive. The device may be embodied as a CVD reactor. The CVD reactor may be a horizontal reactor with a cylindrical coil. This may be an IR heater, as described previously. But the substrate or a susceptor holding the substrate may also be resistance-heated. The coil may be located inside the reactor housing but outside a process chamber housing. The shielding elements may have the shape of flat screens that are driven in rotation about their longitudinal axes or that can be moved parallel to their longitudinal axes. It is considered advantageous if the shielding elements remain inside a heat transfer space in all phases of operation of the device, through which space heat is released from the substrate or susceptor to the cold area. Such a heat transfer space is defined in particular on the one side by the heated surface of the susceptor that is to be cooled in order to change the substrate and on the other side by a cooled surface in particular opposite the substrate or the susceptor. The two surfaces may be the same size, so that the heat transfer space is a cylinder that can have both a circular cross-sectional area and a polygonal cross-sectional area. But the heat transfer space can also have the shape of a truncated cone or truncated pyramid. In a preferred embodiment, it may be provided that the shielding apparatus forms a heat shielding arrangement which has an active area that is at least twice as large during heating of the substrate or the susceptor as an active area during cooling of the substrate or the susceptor. The device may be a warm wall reactor, a planetary reactor or a showerhead reactor.

According to the method according to the invention, a previously described device is initially heated from a first, moderate temperature, which may be, for example, between 50° C. and 200° C., at which the device has been loaded with a substrate, to an elevated temperature, which may be over 1000° C. During this heating phase, the shielding elements are operated in the first operating position so that they provide maximum shielding effect to the flow of heat from the substrate to the cold area. Thermal radiation emitted by the substrate is reflected on the particularly highly reflective surface of the shielding elements. During the process phase, which can also take place at temperatures above 1000° C., the shielding elements are kept in the first operating position. However, it may also be provided that the shielding elements are brought into an intermediate position during the process phase, so that the flow of heat from the substrate is increased thereby. This enables the substrate temperature to be varied by displacing the shielding elements. It may also be provided that only some of the shielding elements are displaced locally differently during the process phase, so that the flow of heat from the substrate can be increased in zones and the substrate temperature or the susceptor temperature can thus be influenced in zones. For this purpose, several sets of shielding elements may be provided, which can be shifted back and forth between the operating positions together, wherein the shielding elements of different sets are able to assume different operating positions. The sets of the different shielding elements can be arranged one behind the other in a flow direction of a process gas through the process chamber. But they can also lie next to each other in the direction of flow. It may further be provided that the different sets of shielding elements are arranged around a common center. In such an arrangement, there can be a central zone in which shielding elements are arranged that can be changed in terms of their operating position independently of one or more radially outer zones. After the process phase has ended, the shielding elements are brought into the second operating position, in which they produce their minimum shielding effect, so that the flow of heat from the substrate to the cold area is maximal. This allows cycle times to be reduced. The installation space can also be reduced because the shielding elements do not leave the heat transfer space when adjusted but lie between the cold area and the hot area to be cooled in both operating positions. An open loop or closed loop control device may be provided, with which the operating positions of the shielding elements can be changed. The open loop control device may interact with a sensor, in particular a temperature sensor, for example with a pyrometer. However, it is also provided that a closed loop control device interacts with one or more sensors to regulate a surface temperature of a susceptor or the substrate to a constant value. The temperature is regulated with a shift of the shielding elements of the one or more zones or sets of shielding elements. If the sensor is a pyrometer, an opening is provided in particular in the housing cover, which can be flushed with an inert gas and/or which is closed with a window. An optical path leads through this opening to the susceptor or to the substrate. The optical path may run through a shielding element. The shielding element may have an opening there, through which the optical path passes. The opening may be a slot.

### BRIEF DESCRIPTION OF THE DRAWINGS

In the following text, the invention will be explained in greater detail with reference to exemplary embodiments. In the drawings:

FIG. 1 is a schematic representation of a first exemplary embodiment of the invention in the manner of a vertical cross section through a reactor housing of a CVD reactor, wherein shielding elements 6 which can be pivoted about respective axes 9 are in their first operating position, in which they exercise a maximum shielding effect on a flow of heat 7 from a susceptor 13 to a cooling apparatus 2,

FIG. 2 shows the section approximately along line II-II in FIG. 1,

FIG. 3 is a representation according to FIG. 1, wherein the shielding elements 6 are in their second operating position, in which they exercise a minimal shielding effect on the flow of heat 7,

FIG. 4 is a representation according to FIG. 1, wherein the shielding elements 6 are in an intermediate position,

FIG. 5 shows a second exemplary embodiment in a representation according to FIG. 1, wherein shielding elements 6′ that can be shifted in a horizontal plane are arranged in the area between gaps between shielding elements 6 and thus have a maximum shielding effect,

FIG. 6 shows the second exemplary embodiment in a representation according to FIG. 3, wherein the shielding elements 6′ are brought into a complete overlapping position with the shielding elements 6 and thus exert a minimal shielding effect,

FIG. 7 shows the second exemplary embodiment in a representation according to FIG. 4, wherein the shielding elements 6′ are in an intermediate position,

FIG. 8 shows the section approximately along line VIII-VIII in FIG. 7,

FIG. 9 shows a third exemplary embodiment of the invention in plan view, wherein the shielding elements 6, 6′ are formed by sector-shaped sections of circular disc-like shielding element carriers 23, 23′,

FIG. 9a shows a variant of the third exemplary embodiment, in which the shielding elements 6, 6′ are arranged over two zones extending concentrically with a center 9, and the shielding elements 6, 6′ of the different zones are able to be displaced individually,

FIG. 10 shows the section along line X-X in FIG. 9, wherein the movable shielding elements 6′ are arranged in the area of gaps between fixed shielding elements 6, filling them in and thus having a maximum shielding effect,

FIG. 11 is a representation according to FIG. 10, wherein the shielding elements 6′ are brought into a complete overlapping position with the shielding elements 6 and thus have a minimal shielding effect,

FIG. 12 is a representation according to FIG. 10, wherein the shielding elements 6′ are in an intermediate position,

FIG. 13 shows a fourth embodiment of the invention in the form of a single horizontal reactor for depositing SiC layers on substrates 3, which are arranged in a process chamber 11 that can be heated from all four peripheral sides with a heating apparatus 4, wherein a shielding apparatus 5 consisting of several shielding elements 6 is arranged between a lower heating apparatus 4 and a lower cold area 2 and between an upper heating apparatus 4 and an upper cold area 2,

FIG. 14 shows a fifth exemplary embodiment wherein, unlike the fourth exemplary embodiment, the shielding apparatus 5 is located between an upper wall of the process chamber 11 and the upper heating apparatus 4 and between a lower wall of the process chamber 11 and a lower heating apparatus 4,

FIG. 15 shows a sixth exemplary embodiment of the invention, wherein a susceptor 13 supports a multiplicity of substrates arranged around a central gas inlet element 14, the susceptor 13 can be rotated and the substrates 3 can lie on rotatable plates, and a shielding apparatus 5 is arranged between a heating apparatus 4 arranged below the susceptor 13 and in a cooled area 2,

FIG. 16 shows a seventh exemplary embodiment of the invention, in which the gas inlet element 14 is designed as a showerhead, and the heating apparatus 4 and the shielding apparatus 5 are arranged as in the sixth exemplary embodiment,

FIG. 17 shows an eighth exemplary embodiment, in which the heating apparatus 4 is a resistance heater or a lamp heater, with which the substrate 3 lying on a transparent susceptor 13 is heated directly by thermal radiation, and a shielding apparatus 5 is arranged between the heating apparatus 4 and a cooled area 2,

FIG. 18 is a perspective, partially cutaway view of a ninth exemplary embodiment of the invention, in which the shielding elements 6 of an upper shielding apparatus 5 and a lower shielding apparatus 5 are each connected to a ceiling plate or base plate of a reactor housing 1, wherein the shielding elements 6 are pivotable,

FIG. 19 shows the section along line XIX-XIX in FIG. 18,

FIG. 20 enlarges the detail XX from FIG. 19, wherein the shielding elements 6 that are connected to each other via a coupling rod 17 are in their second operating position, in which they extend parallel to the flow of heat 7,

FIG. 21 shows the detail XX of FIG. 19, but with shielding elements 6 in the first operating position, in which a highly reflective surface of an insert 22 of the shielding element 6 faces away from the cold area 2,

FIG. 22 is a perspective representation of four strip-like shielding elements 6 coupled with a coupling rod 17 in the second operating position,

FIG. 23 shows the shielding elements 6 of FIG. 22 in the first operating position,

FIG. 24 is a representation similar to FIG. 19, wherein an open loop control device 29 is able to control an actuator for the shielding elements 6, 6′, and cooperates with optical sensors 27 with which the surface temperature of the susceptor 13 or of the substrate 3 can be measured, and

FIG. 25 enlarges the detail XXV from FIG. 24.

### DETAILED DESCRIPTION

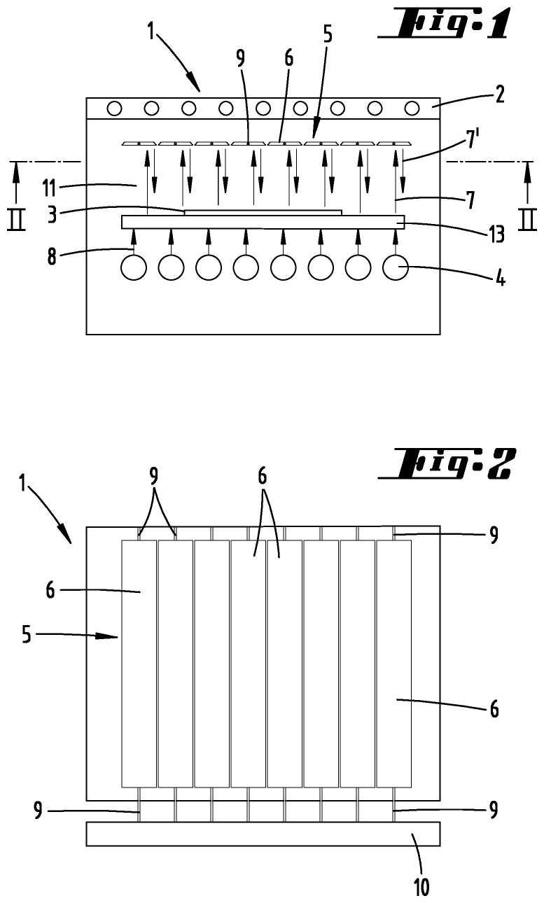

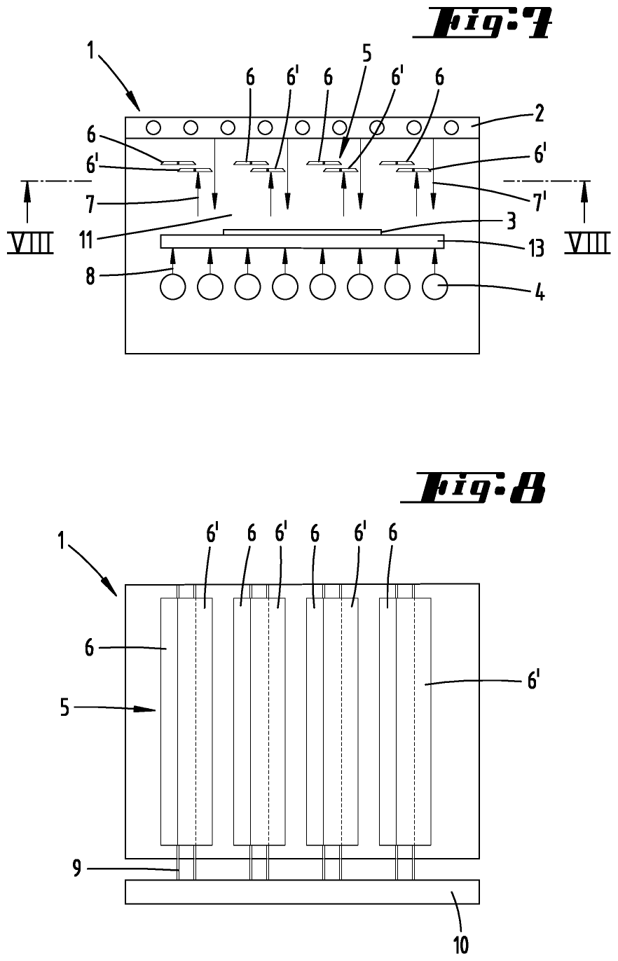

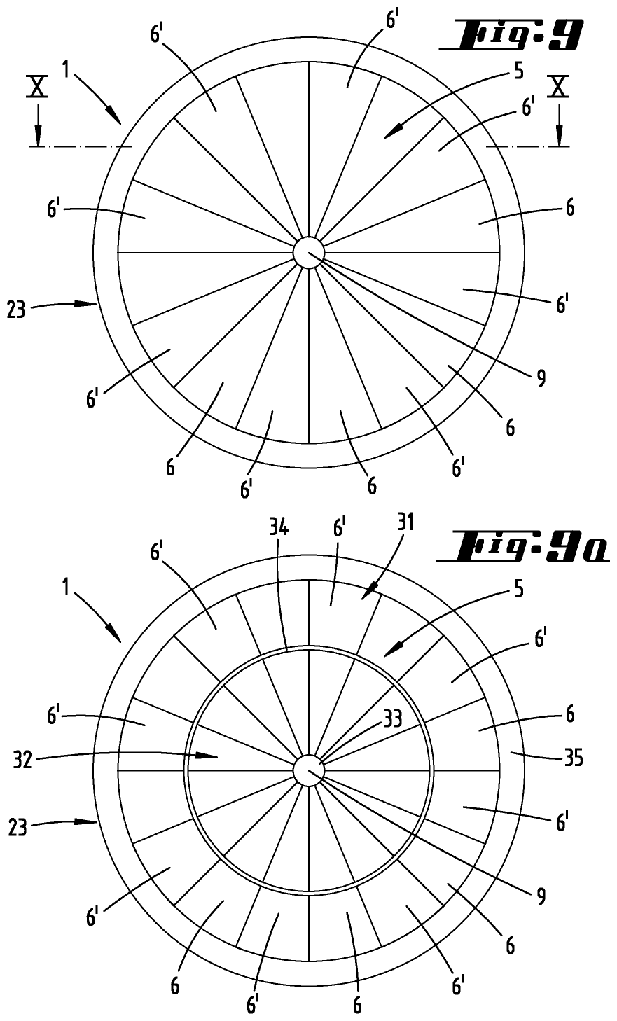

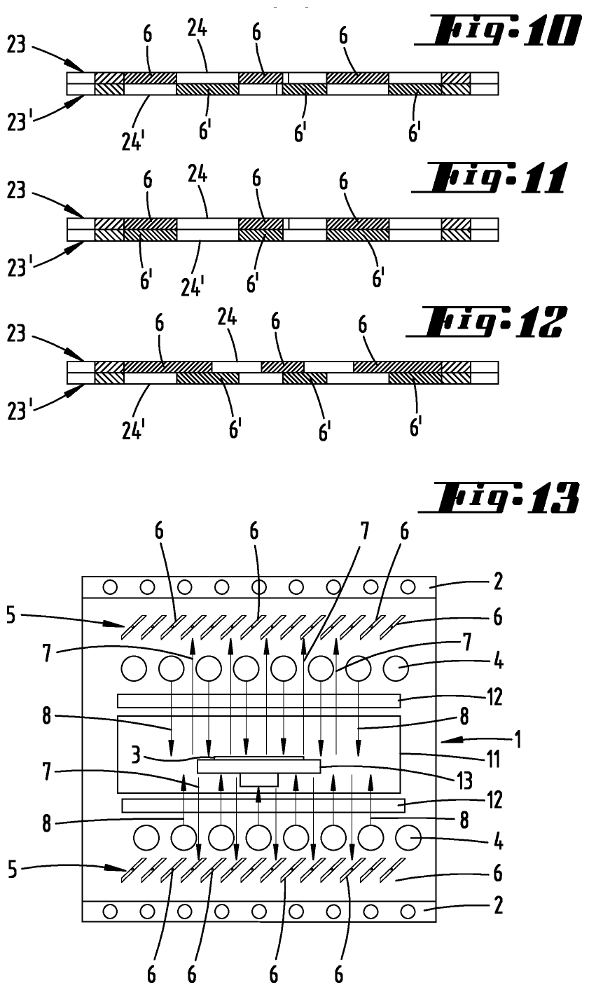

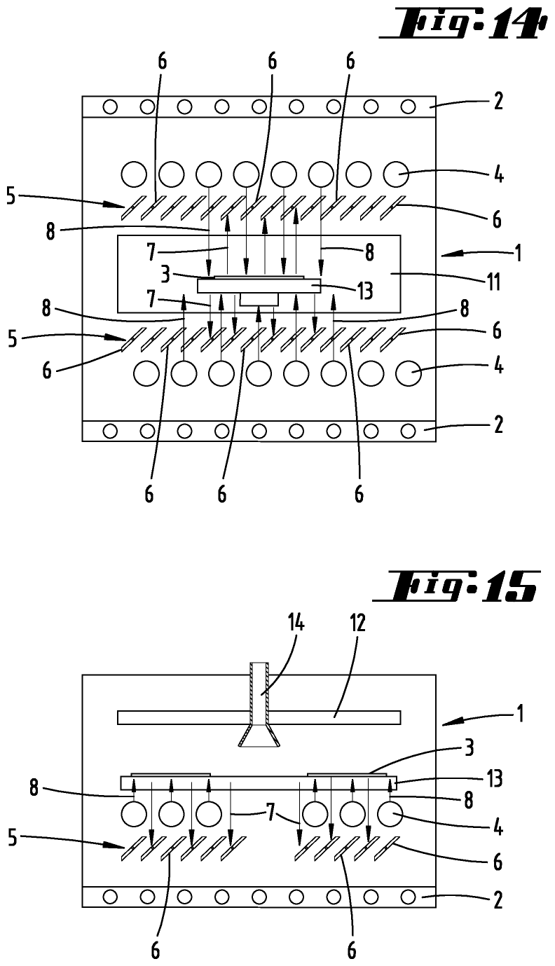

FIGS. 1 to 12 are essentially schematic representations of application examples and embodiment examples of shielding apparatuses 5 according to the invention on a CVD reactor.

In a reactor housing 1, which may be made of stainless steel and can be evacuated, a gas supply line, not shown, opens into a gas inlet element 14, which is only shown in some figures. Process gases are fed into a process chamber 11 with the gas inlet element 14. In the process chamber 11, there is a substrate 3 that is to be coated in a thermal treatment step. For example, silicon carbide can be deposited on the substrate 3 by simultaneously feeding in silane and methane or another silicon compound or carbon compound. A susceptor 13 supporting the substrate 3 is brought to a process temperature of over 1000° C. using a heating apparatus 4, for example an IR heating apparatus. At the process temperature, the process gases react with each other or with the substrate 3 in such a way that a silicon carbide layer is deposited on the surface of the substrate 3. Gaseous reaction products are removed through a gas outlet element, not shown. However, gases and elements of main groups III and V can also be used in the device to deposit III-V layers.

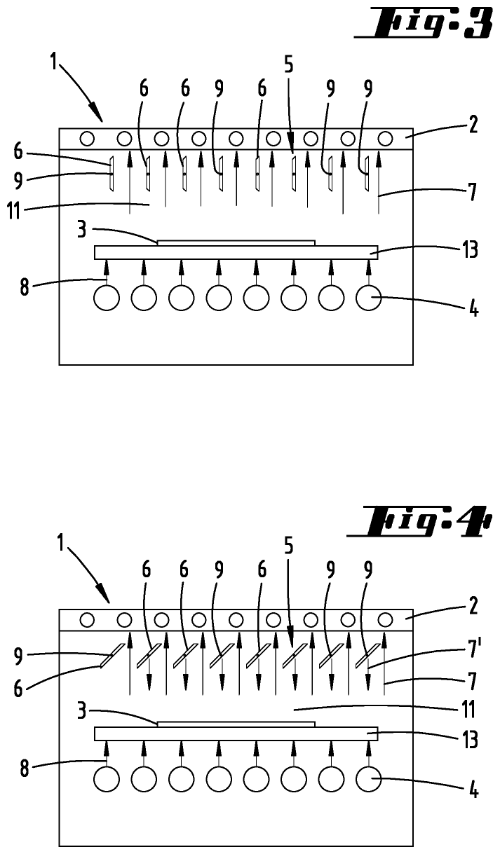

During heating, a power designated with reference numeral 8 flows from the heating apparatus 4 to the susceptor 13 and a flow of heat 7 flows from the susceptor 13 or from the substrate 3 resting on the susceptor 13 away from the susceptor 13 towards a cold area 2 of the reactor housing 1. The cold area 2 may be a cooled wall of the reactor housing 1. In order to influence this flow of heat, there are several shielding elements 6 in the heat transfer path between substrate 3 and the cold area 2, which together form a shielding apparatus 5. FIGS. 2 to 12 show various shielding apparatuses 5. In a first operating position, as shown in FIGS. 1, 5 and 10, these shielding apparatuses 5 are intended to shield and, as far as possible, reflect the flow of heat 7 flowing from the susceptor 13 towards the cold area 2, so that the greatest possible heat return flow 7′ from the shielding elements 6 to the substrate 3 or susceptor 13 is created. This minimizes the heating phase and/or consumes less energy for this purpose.

In the second operating position represented in FIGS. 3, 6 and 11, the shielding elements 6 are shifted within the heat transfer path in such a way that the heat return flow 7′ from the shielding elements 6 to the substrate 3 or to the susceptor 13 is minimized. This shortens the cooling phase.

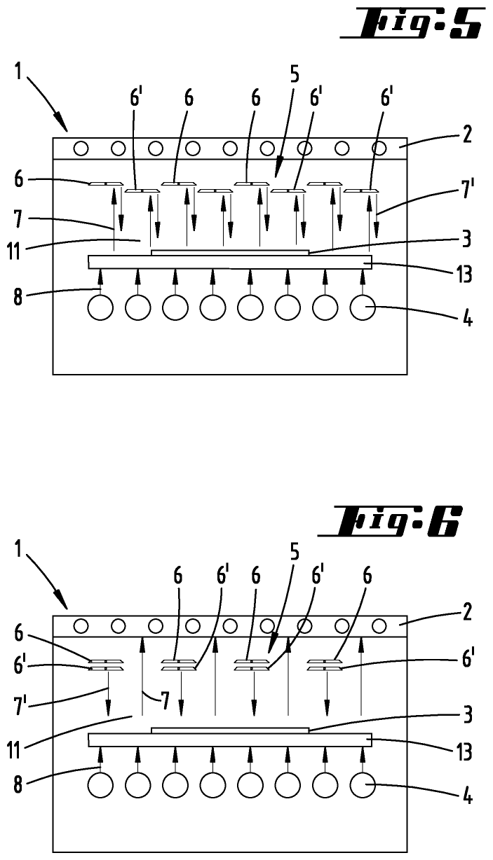

In an intermediate position, as shown in FIGS. 4, 7, 8 and 12, the shielding elements 6 have a reduced shielding effect. Whereas in the first operating position the shielding elements 6 form a highly reflective surface that is as closed as possible and in the second operating position leave as large a free surface as possible between them, the reflective surface can be varied in different intermediate positions. This allows the flow of heat from the substrate or susceptor to be influenced and thus in turn the substrate temperature and/or susceptor temperature. All shielding elements 6 can be coupled to one another. However, they can also be coupled to one another in zones or may be individually adjustable so that the temperature influencing effect can be limited locally.

In the exemplary embodiment shown in FIGS. 1 to 3, the shielding elements are narrow strips that are highly reflective at least on one side. In the first operating position (see FIG. 1), this highly reflective surface faces the substrate 3 or susceptor 13. An axis of rotation extends in the longitudinal center of the shielding element 6, around which the shielding element 6 can be rotated 90 degrees between the positions shown in FIGS. 1 and 3. In the position shown in FIG. 3, a narrow side of the shielding element 6 faces towards the substrate 3 and/or the susceptor 13. The axis of rotation 9 here runs in a plane parallel to the plane of extension of the substrate 3 and/or susceptor 13. The axes of rotation 9 of all shielding elements 6 run parallel to each other.

In the exemplary embodiment represented in FIGS. 5 to 8, the shielding elements 6, 6′ are displaceable in a plane that extends parallel to the plane of the substrate 3 and/or the susceptor 13. There are two sets of shielding elements. The shielding elements 6 form a first set, which is arranged in a first horizontal plane. The shielding elements 6 are spaced apart from each other in the vertical direction by the dimension of their width. Shielding elements 6′ of a second set, which is arranged in a second horizontal plane slightly offset with respect to the first horizontal plane, are situated in the gaps between the shielding elements 6. These shielding elements 6′ may also be spaced apart from each other by the dimension of their width. But the shielding elements 6, 6′ are otherwise identical. The two sets of shielding elements 6, 6′ can be shifted relative to each another, so that the shielding elements 6, 6′ can be brought from a side-by-side position, in which they fill the respective gaps between the other shielding elements 6, 6′, into an overlapping position in which the shielding elements 6 are positioned above the shielding elements 6′, and the gaps between the shielding elements 6, 6′ are free to allow thermal radiation to pass through.

The exemplary embodiment represented in FIGS. 9 to 12 has sector-shaped shielding elements 6, 6′. As with the exemplary embodiment described previously, shielding elements 6 belong to a first shielding element carrier 23, and shielding elements 6′ belong to a second shielding element carrier 23′. The two shielding element carriers 23, 23′ are of the same design and have sector-shaped shielding elements 6, 6′ arranged around a center, between which free spaces 24, 24′ extend, the area of which corresponds to the surfaces of the shielding elements 6, 6′. By relative rotation of the two shielding element carriers 23, 23′ about a vertical axis 9, the free spaces 24, 24′ can be closed, completely open, or partly closed in an intermediate position.

FIG. 9a shows a variant of the exemplary embodiment represented in FIG. 9. First shielding elements 6, 6′ are located in an inner zone 32, which extends around the axis 9. The shielding elements 6, 6′ are mounted between a middle ring element 34 and a central element 33 and can be displaced in the circumferential direction about the axis 9 in such a way that they can be brought from a side-by-side position into an overlapping position. But it is also possible to pivot the shielding elements 6, 6′ in the radial direction relative to the axis 9.

The radially inner zone 32 is surrounded by a radially outer zone 31. In the radially outer zone 31, the shielding elements 6, 6′ lie between an outer ring element 35 and the middle ring element 34. The shielding elements 6, 6′ arranged in the radially outer zone 31 can be shifted independently of the shielding elements 6, 6′ arranged in the inner zone 32. The shielding elements 6, 6′ of the outer zone 31 can be moved back and forth between a side-by-side arrangement and an overlapping arrangement. But they can also be pivoted about axes of rotation extending in the respective plane of extension of the shielding element arrangement, radially to the axis 9.

A preferred exemplary embodiment is shown in FIG. 13. A process chamber 11 is located between two cooled walls that form cold areas 2 inside a reactor housing 1. The process chamber 11 may have a solid housing wall. A gas inlet element, not shown, opens into the process chamber 11. A gas outlet element, not shown, is also provided. Inside the process chamber 11, there is a susceptor 13 which supports a single substrate 3. Reference number 12 denotes an upper and a lower wall that is transparent to alternating electromagnetic fields. The process chamber 11 may be encased all around. The casing formed by the walls 12 may be tubular. This may be a pipe with a circular cross-section or a rectangular cross-section.

A heating apparatus 4 may be arranged around this casing 12. The heating apparatus 4 may be a helical coil that surrounds the walls 12. The coil of the heating apparatus 4 may generate an alternating electromagnetic field which generates eddy currents within the susceptor 13 and thus heats the susceptor 13. However, it is also possible to manufacture the casing 12 from electrically conductive material so that the walls 12 are heated by eddy currents induced therein.

Alternatively, the two heating apparatus 4 may also be designed as spiral coils extending in one plane, with which a heating effect is only generated in the area of two opposing walls 12.

A shielding apparatus 5 is provided below the heating apparatus 4 and above the heating apparatus 4. The shielding apparatus 5 may have a configuration as described above.

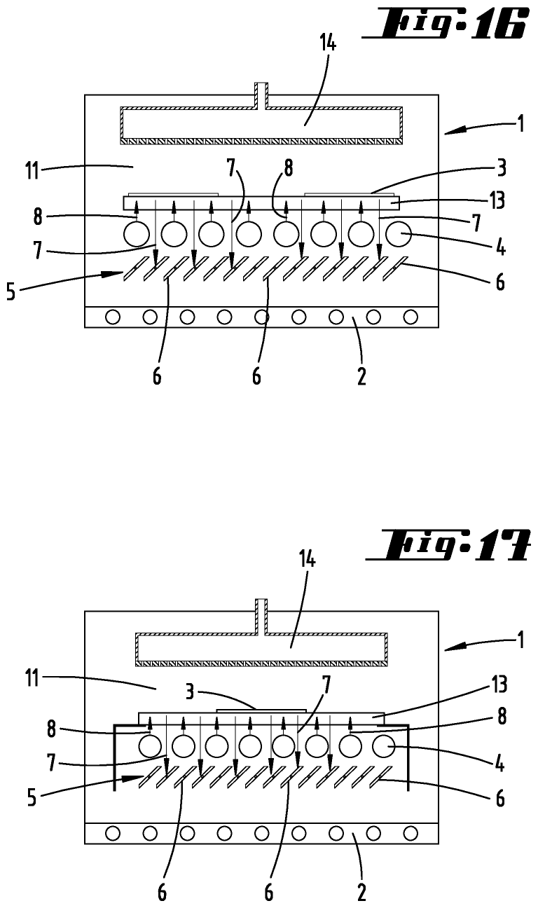

The fifth exemplary embodiment, represented in FIG. 14 essentially only differs from the exemplary embodiment shown in FIG. 13 in that the shielding apparatus 5 is not arranged between the heating apparatus 4 and the cold area, but between the process chamber 11 and the heating apparatus 4.

The heating apparatus may be a coil formed by a pipe. A coolant may flow through the pipe, so that the heating apparatus 4 cools the cold area.

Whereas in the embodiment represented in FIG. 13 the shielding elements 6 may be made of metal, the shielding elements 6 in the embodiment represented in FIG. 14 must be made of a material that is transparent to high-frequency alternating electromagnetic fields.

FIG. 15 shows a sixth exemplary embodiment, in which a gas inlet member 14 opens into a center of a horizontal reactor, in which a plurality of substrates 3 are arranged in a ring around the center on a susceptor 13, which can be rotated about an axis of rotation, not shown. The substrates 3 may in turn lie on substrate supports, which can also be rotated about respective axes of rotation. In this exemplary embodiment, too, the susceptor 13 may be heated with an IR heater 4. A process chamber ceiling 12 may either be cooled or heated here. Here, the shielding apparatus 5 is arranged between a cold area 2 formed by the bottom of the reactor housing 1, which may be actively cooled, and the heating apparatus 4.

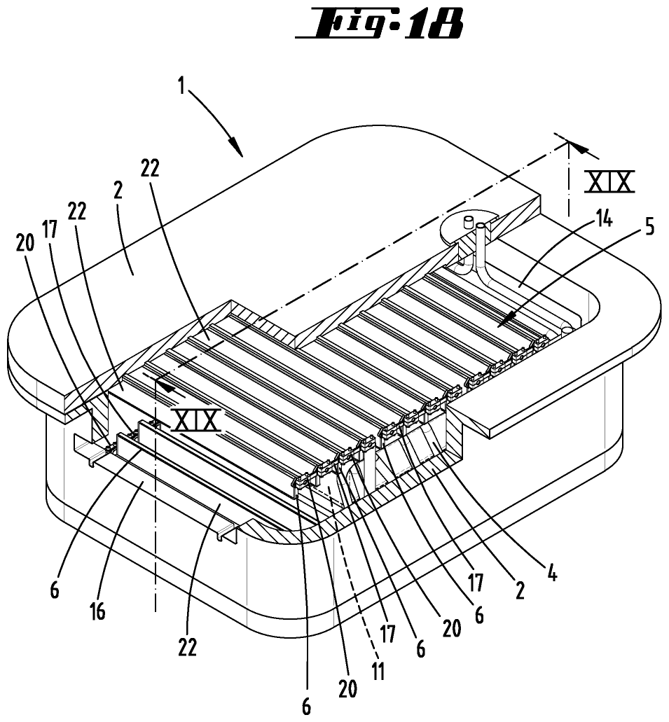

FIG. 16 shows an exemplary embodiment similar to that of FIG. 15. Instead of a central gas inlet element 14, a showerhead extending over the entire area of the susceptor 13 is provided as gas inlet element 14, and has a gas outlet area extending over the entire area of the susceptor 13 with a large number of evenly arranged gas outlet openings.

Whereas in the exemplary embodiments described above the substrate 3 rests on a heated susceptor 13 and is heated by heat conduction from the heated susceptor 13, in the exemplary embodiment represented in FIG. 17, heating apparatuses 4 are provided which heat the substrate 3 directly. The substrate 3 may rest on a support 13 that is transparent to thermal radiation, for example. The heating apparatus 4 may be a lamp heater which heats the substrate 3 directly by thermal radiation. A showerhead is represented here as the gas inlet element 14. However, other gas inlet organs 14 may also be used. Here, the shielding apparatus 5 is arranged between the lamp heater 4 and the cold process chamber floor 2.

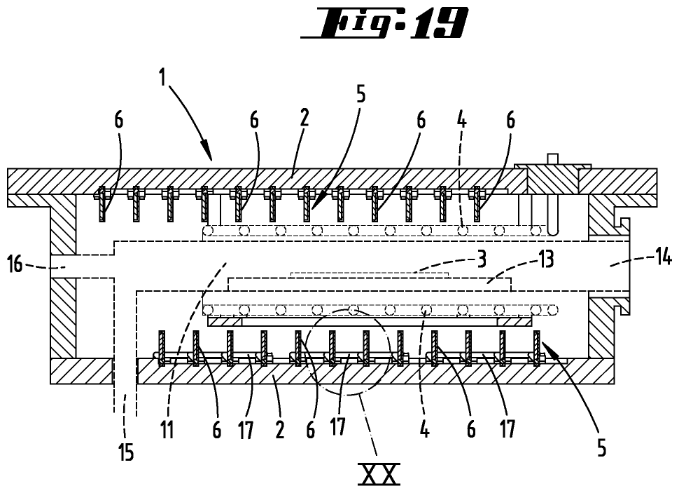

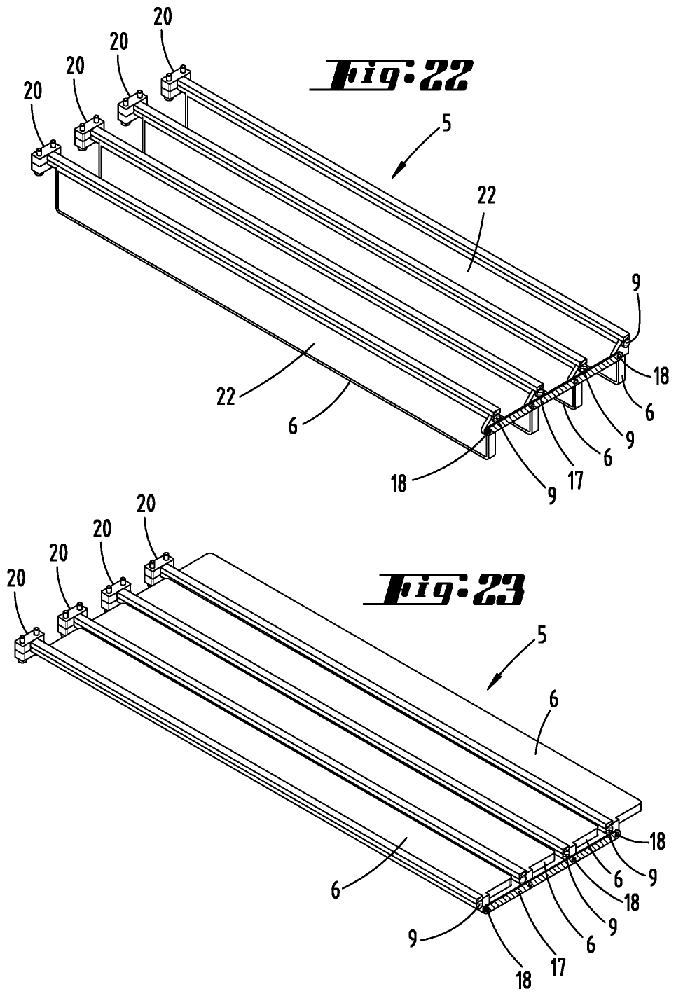

FIGS. 18 to 23 show a preferred exemplary embodiment for depositing SiC. A process gas is fed into a process chamber 11, represented only by dashed lines, which may be tubular as in the exemplary embodiment represented in FIG. 13 and may be surrounded by a cylindrical heating coil 4, via a gas inlet element 14, which is also only shown in outline, and reacts chemically inside the process chamber 11 so that a silicon carbide layer is deposited on a substrate 3. Reaction products can be transported away through a gas outlet element indicated by reference numeral 15. The substrate may be brought into the process chamber 11 and removed from it again through a loading opening 16.

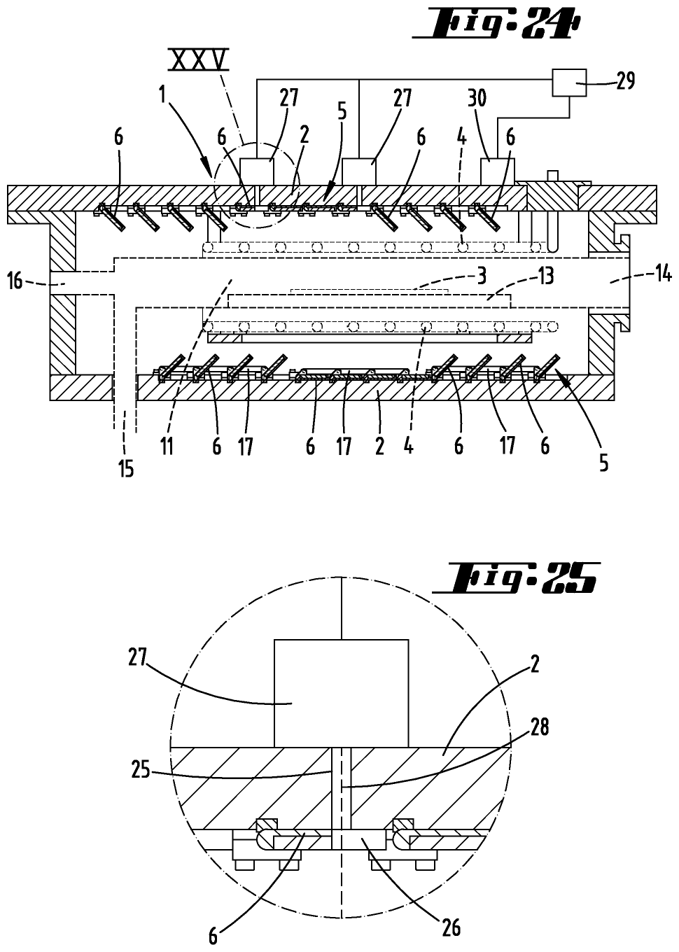

FIG. 24 shows a representation similar to FIG. 19. Optical sensors 27, in particular in the form of pyrometers are provided, with which the surface temperature can be measured in at least one site on the substrate 3 and/or susceptor 13. As shown in the magnified view of FIG. 25, the optical path 28 runs through an opening 25 in the housing ceiling. The opening 25 can be closed with a window and flushed with an inert gas. The optical path 28 runs between the opening 25 and the surface of the substrate 3 or of the susceptor 13. A shielding element 6 located immediately below the opening 25 may have an opening through which the optical path 28 passes even when the shielding element 6 is exerting its greatest shielding effect. The optical path 28 runs in particular through a slot 26 arranged in the shielding element 6.

The shielding elements 6 can be shifted between their operating positions with an actuator 30. FIG. 24 shows only one actuator 30. Multiple sets of shielding elements 6 are arranged on the floor of the reactor housing and on the ceiling of the reactor housing, wherein the shielding elements 6 of each set are able to be displaced by a respective actuator 30 independently of the shielding elements of another set.

With a control device 29, which may include a feedback loop, the shielding elements 6 of the differing sets may be displaced in such a way that the surface temperature of the substrate 3 or of the susceptor 13 may be regulated with respect to a setpoint by the individually adjusted shielding effects.

In this exemplary embodiment, the shielding elements 6 are embodied as strips that can be pivoted about an axis 9, wherein the pivot bearings are arranged directly on the floor or on the ceiling of the reactor housing 1. Both the floor and the ceiling each form cold areas 2, which can also be created with an active cooling apparatus.

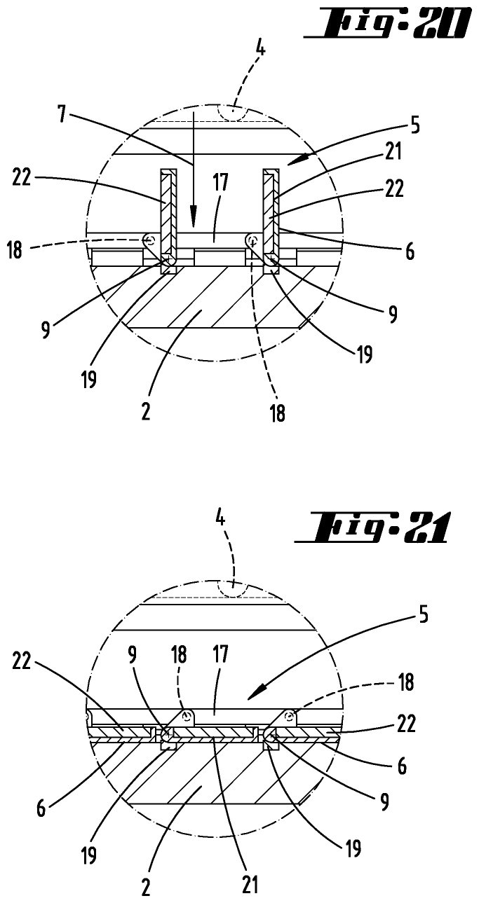

Multiple strip-like shielding elements 6 are articulated by means of a coupling rod 17 via an axis 18 on a short arm of a shielding element 6, so that a linear displacement of the coupling rod 17 leads to a simultaneous pivoting displacement of several shielding elements 6. The shielding elements 6 may thus be pivoted zone by zone between a first operating position represented in FIG. 21, in which they have a strong shielding effect, and a second operating position represented in FIG. 20, in which they have a weak shielding effect.

The shielding elements 6 may be fastened to the floor and/or the ceiling of the reactor housing 1 using a support 19, which may be in the form of a strip. In such a case, the support 19 may sit in a groove. In the first operating position, the rear broad side surface of the shielding elements may bear on a surface of the floor or the cover.

The shielding element 6 may have a shielding body 21 with a recess in which an insert 22 is seated. In the first operating position, represented in FIG. 21, a surface of the insert 22, which is designed to be highly reflective, faces the process chamber 11.

In the second operating position, represented in FIG. 20, the shielding elements 6 protrude substantially vertically from the floor or ceiling.

Bearing blocks 20 may be provided at both ends of the shielding elements 6, with which the shielding elements 6 are fastened to the floor and/or the ceiling.

In summary:

The invention relates to a device for thermally treating a substrate 3, with a heating apparatus 4 arranged in a reactor housing 1 for heating the substrate 3, wherein when heating the device, an output or flow of heat 8 flows from a heating apparatus 4 to a substrate 3, and when cooling, a flow of heat 7 flows from the substrate 3 to a cold area 2. In order to minimize the heating and cooling times, a shielding apparatus 5 for influencing the flow of heat 7 which can be displaced between a first and a second operating position is suggested, wherein the shielding apparatus 5 has a plurality of shielding elements 6, 6′ that can be moved relative to one another.

The invention relates in particular to a device in which the substrate 3 or a susceptor 13 supporting the substrate 3 is heated by a cooled heating apparatus 4 that generates an alternating electromagnetic field, which produces eddy currents in the substrate 3 or the susceptor 13. A return flow of heat from the substrate 3 or susceptor 13 to the heating apparatus 4 can be modulated with the shielding elements 6, 6′.

The preceding notes are intended to explain the inventions covered as a whole by the application, which also further develop the state of the art independently in each case, at least through the following feature combinations, wherein two, more or all said feature combinations may also be combined, specifically:

A device which is characterized in that the shielding elements (6, 6′) are transparent to the alternating electromagnetic fields.

A device which is characterized in that the shielding elements 6, 6′ are arranged between the heating apparatus 4 and the substrate 3.

A device which is characterized in that the pivot axis 18 extends in the area of a longitudinal edge of the shielding element 6 and are arranged near the floor or the ceiling of the reactor housing 1.

A device which is characterized in that the shielding elements 6 are fastened to the reactor housing 1 by means of bearing blocks 20 arranged in the area of the narrow edges of the shielding elements 6, wherein the pivot axes 18 extend through the bearing blocks 20.

A device which is characterized in that a plurality of shielding elements 6 arranged adjustably on the floor or on the ceiling of the reactor housing are coupled to each other by means of a coupling rod 17, wherein a linear displacement of the coupling rod 17 leads to a simultaneous pivoting displacement of multiple shielding elements 6.

A device which is characterized in that the shielding apparatus 5 has a plurality of shielding elements 6, 6′ that are movable relative to each other.

A device which is characterized in that at least one shielding element 6 of the shielding apparatus 5 is rotatable about an axis of rotation 6 that has a directional component perpendicular to the direction of the flow of heat 7, and which is rotated about the axis of rotation 6 to change the operating position.

A device which is characterized in that at least two shielding elements 6, 6′ are arranged so that they at least partially overlap in the second operating position.

A device which is characterized in that a second flow of heat 8 or power flows from the heating apparatus 4 to the substrate 3 through a different or through the same heat transfer space through which the first flow of heat 7 flows.

A device which is characterized in that the axes of rotation 6 of several or all of the shielding elements 9 run perpendicularly to the direction of the flow of heat 7 and extend parallel to each other.

A device which is characterized in that the shielding elements 6 form a closed shielding surface in the first operating position and in the second operating position have been rotated in particular through 90 degrees relative to the first operating position.

A device which is characterized in that two shielding element carriers 23, 23′ form shielding elements 6, 6′ which can be displaced in two planes arranged parallel to one another, wherein the shielding element carriers 23, 23′ are rotatable relative to each other about an axis of rotation 9 perpendicular to the planes, or can be displaced relative to each other in the planes, and wherein one free space 24, 24′ is arranged between each of the shielding elements 6, 6′ of the shielding element carriers 23, 23′, the area expanse of said spaces being equivalent to the area expanse of the adjacent shielding element 6, 6′.

A device which is characterized in that the shielding elements 6, 6′ are narrow, rectangular strips or circular sectors and/or in that the shielding elements 6, 6′ have a surface facing the substrate 3 which has a reflectance greater than 0.6 or has an absorption coefficient less than 0.4 and/or that the one or more shielding elements 6, 6′ are independently adjustable and/or that the shielding elements 6, 6′ are transparent to high-frequency alternating electromagnetic fields.

A method for treating a substrate in a device according to any one of the preceding claims, wherein the shielding apparatus 5 assumes its first operating position during heating of the substrate and its second operating position during cooling of the substrate.

A method which is characterized in that at least one or more of the shielding elements 6, 6′ of the shielding apparatus 5 assume an intermediate position between the first and second operating positions during a substrate treatment step.

A method which is characterized in that a temperature of the substrate 3 or a susceptor 13 is regulated with respect to a setpoint value by means of a control device 29, by shifting the shielding elements 6, 6′ of the shielding apparatus 5.

A method which is characterized in that shielding elements 6, 6′ assigned to different zones are individually adjusted by a respective actuator 30.

All features disclosed are essential to the invention (individually, but also in combination with each other). The disclosure content of the associated/attached priority documents (copy of the prior application) is hereby fully included in the disclosure of the application, also for the purpose of including features of these documents in the claims of the present application. The subclaims, even without the features of a referenced claim, characterize with their features independent, inventive developments of the prior art, in particular in order to make divisional applications based on these claims. The invention specified in each claim may additionally have one or more of the features provided in the above description, in particular features identified with reference numerals and/or specified in the list of reference numerals. The invention also relates to designs in which individual features cited in the preceding description are not implemented, in particular to the extent that they are clearly dispensable for the respective intended use or can be replaced by other technically equivalent means.

### LIST OF REFERENCE NUMERALS

1 Reactor housing
2 Cold area, cooling apparatus
3 Substrate
4 Heating apparatus
5 Shielding apparatus
6 Shielding element
6′ Shielding element
7 First flow of heat
7′ Heat return flow
8 Second flow of heat
9 Axis
11 Process chamber
12 Wall
13 Susceptor
14 Gas inlet
15 Gas outlet
16 Loading opening
17 Coupling rod
18 Axis
19 Supports
20 Bearing block
21 Shielding body
22 Insert
23 Shielding element carrier
23′ Shielding element carrier
24 Free space
24′ Free space
25 Opening
26 Slot
27 Pyrometer
28 Optical path
29 Control device
30 Actuator
31 Outer zone
32 Inner zone
33 Central element
34 Middle ring element
35 Outer ring element

1. A device for thermally treating substrate (3), the device comprising:
a reactor housing (1) with a floor and ceiling;
a heating apparatus (4) arranged in the reactor housing (1), the heating apparatus (4) for heating a first area of the device in which the substrate (3) is located;
a shielding apparatus (5) with a plurality of shielding elements (6, 6′) which are movable relative to each other and are reflective or insulating against a flow of heat,
wherein the shielding apparatus (5) is arranged in a radiated heat transfer path between the first area and a second area (2) of the device configured to have a lower temperature than the first area of the device,
wherein each of the shielding elements (6, 6′) are formed by a narrow strip that can be pivoted about a respective pivot axis (18) between a first operating position and a second operating position,
wherein the shielding apparatus (5) exerts a stronger shielding effect on the flow of heat (7) in the first operating position than in the second operating position,
wherein each of the pivot axes (18) runs in an area of a longitudinal edge of a corresponding one of the shielding elements (6, 6′), and
wherein the shielding elements (6, 6′) comprise bearing blocks (20) that are arranged on the floor or the ceiling of the reactor housing (1).

2. The device of claim 1, wherein the bearing blocks (20) are arranged in an area of respective narrow edges of the shielding elements (6, 6′), and wherein the respective pivot axes (18) pass through a corresponding one of the bearing blocks (20).

3. A device for thermally treating a substrate (3), the device comprising:
a reactor housing (1) with a floor and a ceiling;
a heating apparatus (4) arranged in the reactor housing (1), the heating apparatus (4) for heating a first area of the device in which the substrate (3) is located;
a shielding apparatus (5) with a plurality of shielding elements (6, 6′) which are movable relative to each other and are reflective or insulating against a flow of heat; and
a coupling rod (17) for coupling adjacent ones of the shielding elements (6, 6′) to one another, wherein a linear displacement of the coupling rod (17) leads to a simultaneous pivoting displacement of ones of the shielding elements (6, 6′), wherein the coupling rod (17) is articulated to a short arm of ones of the shielding elements (6) via respective pivot axes (18),
wherein the shielding apparatus (5) is arranged in a radiated heat transfer path between the first area and a second area (2) of the device configured to have a lower temperature than the first area of the device,
wherein the shielding elements (6, 6′) can be pivoted about a respective pivot axes (18) between a first operating position and a second operating position,
wherein the shielding apparatus (5) exerts a stronger shielding effect on the flow of heat (7) in the first operating position than in the second operating position, and
wherein the shielding elements (6) arranged adjustably on the floor or on the ceiling of the reactor housing (1).

4. The device of claim 3, wherein in the first operating position, a rear broad side surface of each of the shielding elements (6, 6′) bears on a surface of the floor or the ceiling.

5. The device of claim 3, wherein the shielding elements (6, 6′) have a surface facing the substrate (3) that has a reflectance greater than 0.6 and an absorption coefficient less than 0.4.

6. The device of claim 3, further comprising a susceptor (13) which supports the substrate (3) and can be heated to temperatures above 1,000° C. by the heating apparatus (4).

7. The device of claim 6, wherein the heating apparatus (4) is a coil which surrounds a process chamber (11) that contains the susceptor (13), and wherein the shielding elements (6, 6′) are arranged outside the coil.

8. The device of claim 3, wherein one of the shielding elements (6, 6′), which is fastened to the ceiling of the reactor housing (1), forms a slot (26) which is aligned with an opening (25) of the ceiling of the reactor housing (1) through which an optical path (28) of a pyrometer (27) passes.

9. The device of claim 8, wherein the shielding elements (6, 6′) are fastened to the floor or the ceiling of the reactor housing (1) with a support (19), that is formed by a strip.

10. A method for treating a substrate (3) in the device of claim 3, the method comprising:
orienting the shielding apparatus (5) in the first operating position during a heating of the substrate (3); and
orienting the shielding apparatus (5) in the second operating position during a cooling of the substrate (3).

11. The method of claim 10, further comprising orienting at least one or more of the shielding elements (6, 6′) of the shielding apparatus (5) in an intermediate position between the first and second operating positions during a substrate treatment step.

12. The method of claim 10, further comprising regulating a temperature of the substrate (3) or a susceptor (13) with respect to a setpoint value by means of a control device (29) that controls a displacement of the shielding elements (6, 6′) of the shielding apparatus (5).

13. The method of claim 10, further comprising:
orienting by a first actuator (30) a first group of the shielding elements (6, 6′) within a first zone of the shielding apparatus (5); and
orienting by a second actuator (30) a second group of the shielding elements (6, 6′) within a second zone of the shielding apparatus (5).

14. The device of claim 1, wherein in the first operating position, a rear broad side surface of each of the shielding elements (6, 6′) bears on a surface of the floor or the ceiling.

15. The device of claim 1, wherein the shielding elements (6, 6′) have a surface facing the substrate (3) that has a reflectance greater than 0.6 and an absorption coefficient less than 0.4.

16. The device of claim 1, further comprising a susceptor (13) which supports the substrate (3) and can be heated to temperatures above 1,000° C. by the heating apparatus (4).

17. The device of claim 16, wherein the heating apparatus (4) is a coil which surrounds a process chamber (11) that contains the susceptor (13), and wherein the shielding elements (6, 6′) are arranged outside the coil.

18. The device of claim 1, wherein one of the shielding elements (6, 6′), which is fastened to the ceiling of the reactor housing (1), forms a slot (26) which is aligned with an opening (25) of the ceiling of the reactor housing (1) through which an optical path (28) of a pyrometer (27) passes.

19. A method for treating a substrate (3) in the device of claim 1, the method comprising:
orienting the shielding apparatus (5) in the first operating position during a heating of the substrate (3); and
orienting the shielding apparatus (5) in the second operating position during a cooling of the substrate (3).
